(19) United States
(12) Patent Application Publication
(10) Pub. No.: US 2003/0030575 A1
(43) Pub. Date: Feb. 13, 2003

(54) Lossless data compression

(75) Inventors: Eitan Frachtenberg, Mevasseret Zion (IL); Shai Revzen, Jerusalem (IL)

Correspondence Address: G.E. EHRLICH (1995) LTD., c/o ANTHONY CASTORINA, SUITE 207, 2001 JEFFERSON DAVIS HIGHWAY, ARLINGTON, VA, 22201, US

(73) Assignee: Harmonic Data Systems Ltd.

(21) Appl. No.: 09/849,316

(22) Filed: May 7, 2001

(51) Int. Cl. H03M 7/34

(52) U.S. Cl. 341/51

(57) ABSTRACT

Dictionary based data compression apparatus comprising: a library of static dictionaries each optimized for a different data type, a data type determiner operable to scan incoming data and determine a data type thereof, a selector for selecting a static dictionary corresponding to said determined data type and a compressor for compressing said incoming data using said selected dictionary. The apparatus is useful in providing efficient compression of relatively short data packets having undefined contents as may be expected in a network switch.

### FIELD OF THE INVENTION

The present invention relates to lossless data compression and more particularly but not exclusively to lossless data compression for small-sized data units.

### BACKGROUND OF THE INVENTION

Data compression is generally divided into two groups, lossy data compression which permits degradation of the data and is generally used for image data and lossless data compression which is fully data preserving and which is generally used for text, program data and the like.

Relating specifically to lossless data compression methods, the majority of methods in use are adaptive, meaning that the method in use adapts to the data that is being compressed. For example a dictionary of commonly appearing data fragments or strings is built up during an initial pass through the data. The dictionary is usually built up so that the most common strings can be referred to using the shortest references. Disadvantages of this method include somehow having to send sufficient data to allow reconstruction of the dictionary at the receiving end and, more importantly, that it is hard to compress short extracts of data since there is not enough data to permit significant adaptation. An example of an adaptive dictionary based compression method is given in U.S. Pat. No. 5,389,922.

Adaptive methods are particularly suitable for cases when nothing is known beforehand about the input data, and they provide a generalized one-size-fit-all algorithm to build a dictionary which is optimized in each case for any data currently being compressed. Generally, adaptive methods place, within the compressed data, information that enables the decompressing process to build the identical dictionary from scratch. This eliminates any need to transfer the dictionary itself to the decompressing process but still incurs a certain size overhead in the compressed data packet since the strings making up the dictionary typically need to be included once in full in the compressed data.

In addition to adaptive methods, there are also non-adaptive methods. Typically in non-adaptive methods, instead of using a dictionary built up dynamically during a pass through the data, a static or pre-defined dictionary is used to compress the data. This has the advantage that the strings comprising the dictionary entries need not be sent since a corresponding dictionary can be pre-stored at the receiving end. Furthermore the method is as suitable for short as for long lengths of data since the dictionary does not need to adapt.

A further advantage of a static dictionary is that since it is created ahead of time, it can be created using large data samples or heavy computing resources not generally available at compression time.

However, the static dictionary is optimal only for the data set for which it was created and may not be the optimal dictionary for data sets likely to be encountered in practice in the course of compression. Indeed, in some cases the static dictionary may not be suitable at all, when for example there is very little correlation between the dictionary entries and the common repeated data sections of the data to be compressed. It is likewise not possible to produce a larger static dictionary optimized for a variety of data types since a larger dictionary requires longer reference strings, thereby reducing compression efficiency. For both of the above reasons a general static dictionary therefore cannot be used for data about which nothing is known about beforehand.

Digital communications networks handle very large quantities of data, generally in the form of data packets. Each of the data packets has to be treated as an autonomous unit since the communications network may not have related packets to hand at any given time. Finding related packets would involve inspection of packet headers and comparison of results which would provide a very heavy load on system resources. Furthermore, decompression reliability may be reduced if decompression of one packet relies upon the availability at the receiver of another packet. Some of the packets contain data already compressed by the sender and others may contain uncompressed data. The kinds of data in the packets varies since the packets are from unconnected sources and involved in unconnected tasks, although a relatively small number of basic data types may be able to cover the vast majority of packets.

It is desirable to compress individual data packets at the network switches for decompression at subsequent switches, thereby to increase network efficiency. As data packets are relatively small, adaptive compression is inefficient. Similarly, as different packets contain different types of data, no single static dictionary can be used.

### SUMMARY OF THE INVENTION

It is an object of the present embodiments to provide a method and apparatus for efficient data compression of small data units whose data type is unknown or variable.

It is a further object of the present embodiments to provide a method and apparatus for data compression, which is applicable to a switching unit of a digital communication network.

According to a first aspect of the present invention there is thus provided a dictionary based data compression apparatus comprising

a library of static dictionaries, comprising at least two static dictionaries each optimized for a different data type,

a data type determiner operable to scan incoming data and determine a data type thereof,

a selector for selecting a static dictionary corresponding to said determined data type and

a compressor for compressing said incoming data using said selected dictionary.

Preferably, the incoming data comprises unrelated data packets, each data packet being of insufficient length to permit efficient adaptive compression.

Preferably, the data type determiner is operable to assign a data type to individual packets.

Preferably, the data types include an unknown type and wherein said compressor is operable not to compress a packet classified as unknown.

Preferably, the data types include at least one text type.

Preferably, the text type comprises statistically spaced text sub-types.

Preferably, the each dictionary comprises a hash table to optimize searching of said dictionary.

A preferred embodiment is incorporated within an interface to a high capacity data link.

Preferably, the said data type determiner is operable to obtain a statistical analysis of relative character frequency from said data, thereby to determine said data type.

Preferably, the compressor is further operable to tag compressed packets to indicate said selected dictionary.

Preferably, the data type determiner is operable to obtain a sample of the data within the packet for scanning and wherein the sample is taken from a position offset from a start of the packet by a predetermined offset, thereby to avoid selecting a sample from a packet header.

According to a second aspect of the present invention there is provided a method of compressing data comprising:

scanning incoming data to determine a data type,

selecting, from a library of static dictionaries, a static dictionary optimized for said determined data type,

and compressing said incoming data using said selected dictionary.

Preferably, the incoming data comprises data characters, the method comprising determining a data type by analyzing relative character content of said data and comparing said relative character content with characteristics of each data type thereby to determine a closest matching data type.

Preferably, the data types comprise a data type for machine executable data which type is identified by a preponderance of the zero character.

Preferably, the data type for machine executable data is further classified into data subtypes for machine architecture.

Preferably, the data is arranged in data packets and wherein scanning of data is carried out on a sample taken from a position offset from a packet start by an offset sufficiently large to avoid packet header data.

A preferred embodiment tags the data to indicate said static dictionary selection.

Preferably, the data types include an “unknown” data type and which method is operable to perform a null compression on data classified as type “unknown”.

Preferably, the dictionaries in said library comprise hashing tables to enable easy searching.

Preferably, the said data types comprise at least one text data type.

According to a third aspect of the present invention there is provided a dictionary based decompression apparatus comprising a library of static dictionaries each optimized for a different data type,

a dictionary determiner operable to scan incoming data and determine a data type of a dictionary used to compress said data,

a selector for selecting a static dictionary corresponding to said determined data type and

a decompressor for decompressing said incoming data using said selected dictionary.

Preferably, the data is arranged in packets having packet headers and said dictionary determiner is operable to search a packet header of an incoming packet to find a tag inserted by a corresponding compression apparatus to indicate said data type.

Preferably, the decompressor is operable to carry out a null compression operation on any packet identified by said tag as not having a selected data type.

Preferably, a compression performance threshold is set, and said compressor is operable to reidentify any data type whose compression does not reach said performance threshold as being of unknown type.

Preferably, the decompressor comprises an LV type decompression procedure.

Preferably, the data types include at least one text data type.

Preferably, the data types include at least one executable data type.

A preferred embodiment comprises a bogus data identifier operable to stop a current decompression operation if a current data packet associated with a given dictionary appears to contain data out of a range of said dictionary.

According to a fourth aspect of the present invention there is provided a method of decompressing data comprising,

receiving data that has been compressed using one of a plurality of static dictionaries from a static dictionary library,

determining from said received data which one of said plurality of dictionaries has been used to compress said data, and

decompressing said data using said determined dictionary.

Preferably, the data is in the form of data packets having headers and wherein said determining is carried out by identifying an indication tag within said packet header.

Preferably, the dictionaries include a dictionary for machine executable data.

Preferably, the packets further include an “unknown” packet type and which method is operable to perform a null decompression operation on packets identified as type “unknown”.

Preferably, the data types comprise at least one text data type.

Preferably, the decompression includes checking said data to ensure that it is within a range of said selected dictionary and aborting said decompression if it is outside a range of said dictionary.

According to a fifth aspect of the present invention there is provided apparatus for building a library of static compression dictionaries, said apparatus comprising

test data categorized into a plurality of data types,

an adaptive dictionary builder for building dictionaries optimized for an input data set,

an input unit for inputting, to said adaptive dictionary builder, test data of a single data type for each one of a plurality of dictionaries to be built,

and a memory for storing a plurality of dictionaries, each built using a different test data type, thereby to form a library of static compression dictionaries.

Preferably, the adaptive dictionary builder comprising LZ type dictionary building functionality.

In a preferred embodiment, the adaptive dictionary builder further comprises a hash table constructer for constructing a hash table for rapid searching of said dictionary.

Preferably, the adaptive dictionary builder comprises a string evaluation unit for assigning compression utility values to repeated strings identified within said data, thereby to provide a relative prioritization for incorporation of said data strings into said respective dictionary.

Preferably, the string evaluation unit is operable to generate a string utility value by computing a difference between a length of a given string and a length of a reference of a position thereof in a dictionary.

Preferably, the string evaluation unit is operable to order evaluated strings in an order of respective string utility values.

A preferred embodiment includes a dictionary optimizer for optimizing each respective dictionary by merging similar strings incorporated within said dictionary.

The dictionary optimizer may optimize each respective dictionary by merging strings entered into said dictionary using a string merging heuristic.

According to a sixth aspect of the present invention there is provided a method of building a static dictionary library, the method comprising:

inputting test data,

categorizing said test data into a plurality of data types,

building an adaptively optimized dictionary for each one of said data types, and

storing each adaptively optimized dictionary together to form said library.

Preferably, the building of said dictionary comprises using an LZ type dictionary building process.

A preferred embodiment includes constructing a hash table for rapid searching of said dictionary.

A preferred embodiment preferably includes assigning compression utility values to repeated strings identified within said data, thereby to provide a relative prioritization for incorporation of said data strings into said respective dictionary.

A preferred embodiment comprises generating a string utility value by computing a difference between a length of a given string and a length of a reference of a position thereof in a dictionary.

A preferred embodiment comprises ordering evaluated strings in an order of respective string utility values.

A preferred embodiment comprises ordering evaluated strings according to frequency.

A preferred embodiment comprises optimizing each respective dictionary by merging similar strings incorporated within said dictionary.

A preferred embodiment comprises optimizing each respective dictionary by merging strings entered into said dictionary using a string merging heuristic.

Preferably, the categorizing of said data comprises making character frequency analyses of said data and associating together data having a similar character frequency characteristic.

According to a seventh aspect of the present invention there is provided a method of building a static dictionary library, the method comprising:

inputting test data categorized into a plurality of data types,

building an adaptively optimized dictionary for each one of said data types, and

storing each adaptively optimized dictionary together to form said library.

Preferably, the building of said dictionary comprises using an LZ type dictionary building process.

A preferred embodiment comprises constructing a hash table for rapid searching of said dictionary.

A preferred embodiment comprises assigning compression utility values to repeated strings identified within said data, thereby to provide a relative prioritization for incorporation of said data strings into said respective dictionary.

A preferred embodiment comprises generating a string utility value by computing a difference between a length of a given string and a length of a reference of a position thereof in a dictionary.

A preferred embodiment comprises ordering evaluated strings in an order of respective string utility values.

A preferred embodiment comprises optimizing each respective dictionary by merging similar strings incorporated within said dictionary.

A preferred embodiment comprises optimizing each respective dictionary by merging strings entered into said dictionary using a string merging heuristic.

Preferably, the adaptively organized dictionaries are each of different size.

Preferably, the adaptively organized dictionaries are each usable in incompatible compression procedures.

According to an eighth aspect of the present invention there is provided an apparatus for classifying incoming data, comprising:

a data scanner for scanning incoming data to provide a statistical analysis thereof, and

a type associator for using data of said statistical analysis to step through characteristics of predetermined data types, thereby to associate said data with one of said data types.

According to a ninth aspect of the present invention there is provided an apparatus for classifying incoming data, comprising:

a library comprising statistical data sets for each one of a plurality of data types,

a data scanner for scanning incoming data to provide a statistical analysis thereof,

a type matcher for finding a closest matched between said analyzed data and said statistical data sets, thereby to determine a most probable data type of said incoming data.

According to a tenth aspect of the present invention there is provided a method of classifying incoming data in accordance with a library of data types, comprising:

scanning incoming data to obtain a statistical analysis thereof,

using said statistical analysis to step through a series of data type characteristic selection rules,

determining a closest match between said incoming data and said respective data types from said selection rules,

thereby to obtain a most probable data type of said incoming data.

According to an eleventh aspect of the present invention there is provided a method of classifying incoming data in accordance with a library of data types, comprising:

scanning incoming data to obtain a statistical analysis thereof,

comparing said analysis with each one of a plurality of sets of statistics each corresponding to a respective data type in said data type library, and

determining a closest match between said incoming data and said respective data types,

thereby obtaining a most probable data type of said incoming data.

According to a twelfth aspect of the present invention there is provided a selective packet compression device comprising:

a packet classifier for classifying incoming data packets into precompressed packets and non-compressed packets and

a compressor connected to said packet classifier to be switchable by said packet classifier to compress packets classified as non-compressed packets and not to compress packets classified as precompressed packets.

Preferably, the incoming data comprises unrelated data packets, each data packet being of insufficient length to permit efficient adaptive compression.

Preferably, the data type determiner is operable to assign a data type to individual packets.

Preferably, the data types include an unknown type and wherein said compressor is operable not to compress a packet classified as unknown.

Preferably, the data types include at least one text type.

Preferably, the text type comprises statistically spaced text sub-types.

Preferably, each dictionary comprises a hash table to optimize searching.

A preferred embodiment is incorporated within an interface to a high capacity data link.

Preferably, the data type determiner is operable to obtain a statistical analysis of relative character frequency from said data, thereby to determine said data type.

Preferably, the compressor is further operable to tag compressed packets to indicate said selected dictionary.

Preferably, the data type determiner is operable to obtain a sample of the data within the packet for scanning and wherein the sample is taken from a position offset from a start of the packet by a predetermined offset, thereby to avoid selecting a sample from a packet header.

According to a thirteenth aspect of the present invention there is provided a selective packet compression method comprising:

classifying incoming data packets as compressed packets and non-compressed packets,

compressing those incoming data packets classified as non-compressed packets, and

not compressing those incoming data packets classified as compressed packets.

According to a fourteenth aspect of the present invention there is provided a static compression dictionary library comprising:

a plurality of individually selectable static compression dictionaries, each dictionary being optimized for compression of data of a predetermined data type.

According to a fifteenth aspect of the present invention there is provided a method of classifying a data packet into one of a plurality of data types based on character content of the data of the packet, the method comprising:

obtaining a first data string beginning at a predetermined offset from the beginning of the packet,

analyzing the data string for character distribution, and

classifying the packet based on the character distribution.

A preferred embodiment comprises obtaining a second string at a predetermined offset from said first string and analyzing said second string for character distribution.

According to a sixteenth aspect of the present invention there is provided a compressor for compressing data by replacing data with a corresponding start position and a length of a location of said data in a data dictionary, said replacements giving a statistical correlation between length and frequency such as to provide a progression between more frequent lengths and less frequent lengths, the compressor comprising an encoder operable to encode said lengths such that said statistically more frequent lengths are encoded using shorter codes than said statistically less frequent lengths, a statistically most frequent length being encoded with a shortest code.

According to a seventeenth aspect of the present invention there is provided a method of building a hash table for a string-based compression dictionary, said string-based compression dictionary comprising a string of concatenated repeating data portions of target compressible data, parts of the string being referable by a start position and a length, the method comprising:

passing through all positions on said string, and

for each position on said string repeating for all string lengths between a minimum string length and a maximum string length:

computing a hash value for the string part at the current position and having the current string length,

entering the current position in the hash table at a position of the computed hash value if said position of the computed hash value is empty, and

entering the current position at a subsidiary position of said computed hash value if said position of said computed hash value is already occupied.

According to an eighteenth aspect of the present invention there is provided a method of finding a location of a longest string part within a string based compression dictionary referenced via a hash table with table entries and associated sub-entries, and an associated hash function, the method comprising:

applying successively incrementally increasing lengths of said string part to said hash function to obtain a hash result,

applying said hash result to said hash table to obtain a location in said dictionary,

and when a location is not retrieved from said hash table then providing a last previous obtained location as an output if a preceding incrementally increasing length of said string yielded a location, and otherwise indicating a retrieval failure.

### BRIEF DESCRIPTION OF THE DRAWINGS

For a better understanding of the invention and to show how the same may be carried into effect, reference will now be made, purely by way of example, to the accompanying drawings.

With specific reference now to the drawings in detail, it is stressed that the particulars shown are by way of example and for purposes of illustrative discussion of the preferred embodiments of the present invention only, and are presented for providing what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice. In the accompanying drawings:

FIG. 1 is a simplified diagram showing a part of a communications network including a high capacity link,

FIG. 2 is simplified block diagram showing a compression decompression unit according to a first embodiment of the present invention,

FIG. 3 is a simplified block diagram of the device of FIG. 2 in greater detail,

FIG. 4A is a simplified block diagram of the type determiner of the device of FIG. 3,

FIG. 4B is a variation of the type determiner of FIG. 4A,

FIG. 5 is a simplified block diagram of a dictionary creator in accordance with an embodiment of the present invention, and

FIG. 6 is a simplified block diagram of device for categorizing test data into data types for use in the dictionary creator of FIG. 5.

### DESCRIPTION OF THE PREFERRED EMBODIMENTS

Before explaining at least one embodiment of the invention in detail, it is to be understood that the invention is not limited in its application to the details of construction and the arrangement of the components set forth in the following description or illustrated in the drawings. The invention is applicable to other embodiments or of being practiced or carried out in various ways. Also, it is to be understood that the phraseology and terminology employed herein is for the purpose of description and should not be regarded as limiting.

Reference is now made to FIG. 1, which is a simplified block diagram showing part of a digital communications network. A first trunking network 10 is connected via a switch or router 12 to a high capacity link 14. The high capacity link may typically be a high capacity optical fiber link or a microwave or satellite link. The far end of the high capacity link 14 is connected to a second switch or router 16 which is in turn connected to a second trunking network 18. The switches 12 and 16 direct data packets arriving from the trunking networks to the appropriate high capacity link according to address information stored in packet headers.

The switches 12 and 16 preferably serve inter alia as interfaces for the high capacity link in that they carry out operations on the data that make for more efficient use of the high speed data link. A particularly useful operation for increasing the capacity of the link is compression of the data packets. However, compression of data packets at the network switch level is problematic because of the short packet length and the mixture of data types.

More particularly, data packets arriving at the switches may be any kind of packet traveling across the network. Some of the packets may have been compressed by a sending application, some may have been compressed by other parts of the network and some may be uncompressed. In addition to being compressed or uncompressed, different packets may contain different types of data in terms of packet content. For example some packets may contain audio or visual data files, others may be text files, the text itself being in any one of a wide variety of languages. Some packets may contain run length encoded data, e.g. fax data, and some packets may contain executable code. Each of these data types follows different statistical patterns and has different properties such that a static compression dictionary optimized for one type is practically useless for any of the others. Furthermore the packet size is not large enough to allow an adaptive dictionary to effectively be built up. Digital communications networks handle very large quantities of data, generally in the form of data packets. Each of the data packets has to be treated as an autonomous unit since the communications network may not have related packets to hand at any given time. Finding related packets would involve inspection of packet headers and comparison of results which would provide a very heavy load on system resources. Furthermore, decompression reliability may be reduced if decompression of one packet relies upon the availability at the receiver of another packet.

In prior art systems which compress data packets at the network switch level, much effort is expended in compressing data packets that have already been compressed once, so that the benefits of further compression are minimal.

Reference is now made to FIG. 2, which is a simplified block diagram of a compression/decompression device according to a first embodiment of the present invention for use in the switches 12 and 16 of FIG. 1. In FIG. 2 the compression/decompression device comprises a compression path 20 and a decompression path 22. The two paths share a common library 24 of static compression dictionaries. As will be explained in greater detail below, the compression path is able to examine incoming packets for statistical qualities, thereby to determine a data type of the packet. The determined data type is then used to select a static compression dictionary from the library 24, corresponding to the selected data type, and then the packet is compressed using the selected dictionary in any one of a series of techniques known to the skilled man, which techniques essentially replace strings of data with references to their location in the dictionary. It is noted that whilst most methods rely on so-called “LZ-based compression”, some other methods can also be considered under “dictionary compression”. One example is the well-known, efficient and mostly unpatented family of so-called “Huffman compression” techniques.

As will be exemplified below, the statistical examination is additionally able to determine that a data packet does not fit any of the available data types, in which case the packet is preferably not compressed. Such an event may occur for example when the data packet is already compressed. A decision not to compress a seemingly random packet (i.e compressed, encrypted, or otherwise random) however, need not merely be the default case of the type selector. It can be an explicit choice for improving overall compressor performance.

The possible data types may be any one of a plurality of-predetermined data types, limited only by the ability of a classification scheme to be able to classify data as belonging thereto. There is no other limitation on the number or kind of data types, and any criteria may be used in classification, but in order to obtain fast compression together with a high compression ratio, the classifier preferably ascribes the same data type to units of data having similar contents in information-theory terms. To each of the predetermined data types a pre-constructed specific dictionary is assigned, except for data types that it is not desired to compress using a static dictionary. Such types may include already compressed data, and may also include other data types for which dictionary-based compression is not the most suitable method, and they may also include data packets for which classification simply has not succeeded.

The data packets are then compressed using the specific dictionary associated therewith. Those packets with which the classification scheme has not succeeded in associating a dictionary are preferably left uncompressed.

Preferably, the data packet is tagged with an indication as to whether it has been compressed or whether it has been left alone, and if it has been compressed then it is also tagged with an indication of the data type that has been used. It is noted that the tag may include error correction information. Error correction information added at any earlier stage of the compression algorithm would be liable to be removed by later stages of the compression.

The tags may also serve to define a compression method as well as a static dictionary. Certain data types may be more suited to non-dictionary compression methods. Such data types once identified may be compressed using the associated compression method rather than a given static dictionary and tags may be used to indicate to the receiver the compression method used.

As will be explained in more detail below, the specific dictionary is any representation of recurring strings found to be common in the given data type, the representation being suitable for efficient use by the compressor or decompressor, for example an LZ-type compressor/decompressor. The dictionary may be any one of a range of variations on the LZ type, or may be designed for other dictionary-based compression methods such as Huffman encoding. A preferred embodiment comprises a dictionary which is simply a long concatenation of recurring data strings from the class.

A preferend embodiment of a static dictionary also has as little redundancy in it as possible, so that it can contain more data for a fixed size or alternatively, use less space and shorter references. Reduction in redundancy may be achieved by what is known as pruning, as will be described in more detail below.

The decompression path 22 preferably carries out the complementary operation of the compression path 20 in that it determines which, if any static dictionary from the static dictionary library 24 has been used to compress a current incoming data packet. It will be appreciated that the static dictionary library at the decompression end is the same as the library at the compression end

Preferably, in the decompression path such a determination does not involve a statistical analysis but rather may be read from the tag information added to the packet header by the compression path 22 as explained above. The relevant dictionary is selected and is used to decompress the data in a standard decompression operation in which reference strings in the compressed data are replaced with the corresponding strings in the dictionary. Identification data or tags are then removed from the data packet, including tags that indicate that no compression was carried out, and on which packets no decompression is needed.

The use of a fixed library of static compression dictionaries, which can be held independently at both the compression and decompression ends of the operation, has the advantage that the dictionary entries do not need to be sent along with the compressed data. For short excerpts of data such as typical length data packets there is thus obtained a considerable advantage in terms of obtained compression ratio.

Reference is now made to FIG. 3, which is simplified block diagram showing the device of FIG. 2 in greater detail. Parts that are identical to those shown above are given the same reference numerals and are not referred to again except as necessary for an understanding of the present embodiment. In FIG. 3, a data compression path comprises an input buffer 30 for receiving undefined data packets from a network. A type determiner 32 scans the incoming data packet to obtain various statistics of the data content of the packet. As will be explained in more detail below, statistics for scanning may be selected in such a way as to permit effective selection of a static dictionary from the static dictionary library 24 that is best suited for compression of the incoming data packet. The type determiner 32 in one embodiment compares the statistics it has obtained with sets of corresponding statistics for each one of the data types available, meaning each data type corresponding to a dictionary in the library.

In another embodiment, the type determiner 32 uses the statistics obtained as the input to a recognition algorithm, as will be explained below.

Typical data types may include text data, executable file data, and unclassified data. In a preferred embodiment, text data is further classified into different languages. Each data type used has its own specialized dictionary. Executables can also be further classified, for example according to target architectures. Likewise, text can be further classified to popular content types which include HTML, JavaScript, etc.

The comparison or algorithm preferably leads to the selection of a closest possible data type including a type unknown, and the result is then passed to a selector 34. The selector 34 then selects a static dictionary of corresponding type from the library 24 which may then be used by compressor 36 to compress the data packet as explained above. If a type of unknown is selected then preferably the compressor 36 carries out a null operation. Preferably, a marker or tag is added to the packet header, as explained above, to indicate which static dictionary, if any, has been used and the compressed data packet is then passed on to output buffer 38 for sending on via the network.

In a further preferred embodiment of the present invention a mistyping detector is provided at the compressor. Operation of the mistyping detector is as follows: It may happen that a packet is tagged as a given type, e.g. TEXT, and an attempt is made by the compressor to compress the packet. However, the resulting compressed packet size is the same as or actually larger than the original packet size. Such poor compression behavior can arise from wrong type identification, or an unsuitable dictionary for the packet at hand. Such packets are best re-tagged as type UNKNOWN, and sent over the channel uncompressed, partly to avoid increasing the packet size and partly to avoid unnecessary processing on the decompressing side. Furthermore, it is pointed out that it is worthwhile to recognize such uncompressible packets as early as possible in the compression process to avoid wasteful processing at the compressor side as well, and thus the mistyping detector may use a threshold factor to check, during the compression process whether or not worthwhile compression is being gained and thus whether the packet is worth continuing working on, or whether it would be better to tag it as UNKNOWN at this point and continue. Threshold checking can be carried out continuously (i.e. compression performance is measured continously and compression is aborted whenever below the threshold), or at discrete checkpoints, e.g. every 100 bytes of processing or so.

The compressor 36 preferably comprises as efficient as possible an implementation of a variant of the Lempel-Ziv (LZ) family of compression algorithms. The most important difference between the algorithm of the compressor 36 and conventional LZ-variants is the use of a static dictionary as discussed above. Most conventional LZ-based coders construct a data dictionary on the fly, by analyzing the data as it is being compressed. The analysis requires a sizeable amount of data in order to obtain a reasonable compression ratio (at least a few Kbytes), and also has a substantial CPU-resource cost as well. When dealing with packets formed using the Internet Protocol, which are typically small (generally having a maximum size of about 1.5 Kbytes), an adaptive solution does not work on a packet basis. Attempting to identify associated packets and carrying out compression across packet boundaries is, however, both complex and unreliable since packet headers would have to be read and remembered and decompression could only be performed if all the packets arrived successfully at the destination.

Thus, in the present embodiment, the building of compression dictionaries is carried out in advance. As will be explained below, offline data analysis can be more thorough, allows a rigorous classification of data to be carried out and thus permits the creation of “optimal” dictionaries to an extent unfeasible in real time due to the prohibitive resource cost.

The use of pre-built dictionaries also has certain disadvantages: small dictionaries created adaptively at runtime are more context-sensitive, require fewer bits to code, and can therefore provide better compression ratios. However, since the vast majority of data being exchanged over networks belongs to a small number of clearly defined data types which are statistically quite stable (typically HTTP, Java, English text, executables,), a set of static dictionaries generally provides a fairly adequate representation.

Considering possible compression algorithms in further detail it may be stated that the task of the compressor 36, given a data buffer to encode, is to produce a smaller buffer containing the same data, compressed, or to perform a null operation if the type determiner has indicated that the data seems incompressible. Preferably the data has been labeled with an appropriate type flag by the type determiner 32, as discussed above so that the appropriate dictionary may be selected by the selector 34. Provided a dictionary is selected the data is coded by the algorithm in table 1 below using the selected type-specific dictionary.

In the algorithm of Table 1 a first byte or character is selected. The following byte or character is added and positions in the dictionary containing the combination are noted. Further bytes are added as long as a corresponding string can still be found, but generally, as the selection gets longer the chances of finding a corresponding string in the dictionary fall. When the longest possible match has been found then the match is compared to a threshold encoding length, usually of three bytes or characters. If the match is shorter then the match is retained as is in the packet, flagged in front with a “0”. If the match is longer then a “1” is inserted indicating a data match and then the match itself is replaced with a pointer to the first byte of the match in the dictionary and the match length. A further possibility is no match at all, which may be considered as a too-short match.

Efficient compression may be obtained using the above algorithm provided that enough relatively long matches are found in the dictionary that

TABLE 1
Compression Algorithm

Loop through bytes in the input buffer
Find the longest string σ, in the dictionary that matches the buffer
starting from the current pointer.
If the string σ has a length shorter than a predetermined constant:
Output ‘0’ (one bit)
Output the current data byte (8 bits)
Increment byte counter, and continue with step 2
Otherwise, if a match is found (σ having a length equal to or greater than
a constant:
Output ‘1’ (one bit)
Output σ's dictionary position (fixed size per dictionary)
Output σ's length in bytes (variable no. of bits)
Advance byte counter by σ's length and continue with step 2

can be replaced with the shorter encoding of dictionary reference pairs viz <position, length>.

In a preferred embodiment, encoding of a match's length within compressed output is made more space-efficient by exploiting the fact that match lengths are not distributed uniformly: Most matches are short, and the number of matches decreases dramatically with match length. A method for exploiting this fact was first suggested by Friend R. & Monsour R., “IP Payload compression using LZS”, RFC-2395, 1998, also http://www.iets.org/rfc/rfc2395.txt the contents of which are hereby incorporated by reference.

A preferred embodiment of the encoder 36 uses a modification of the method of Friend and Monsour as described below. Table 2 below shows a comparison of compression ratios obtained experimentally using three different match-length encoding methods (lower ratios indicating better results). Compression ratio may be defined simply as the total size of the compressor output (including tags and any other control data) divided by total size of the compressor input. The dictionary size in each case is expressed in bits (log₂ of the actual dictionary size in bytes). The fixed encoding method in the experiment used 6 bits to encode the match length (thus limiting a match to no longer than 64 bytes, a very realistic limit). The LZS variable method in the experiment involved encoding bits using the variable-length encoding offered by Friend and Monsour referred to above. The modified variable method is that of the present embodiment which is similar to Friend and Monsour but is biased towards shorter matches (for example requiring only a single bit to express a match length of 3—generally the most common match length).

TABLE 2
Comparative compression Ratios for Different
Length Encoding Schemes

| Dictionary | Fixed | LZS | Modified |
|---|---|---|---|
| size | encoding | variable | variable |
| 12 | 86.28% | 82.04% | 82.07% |
| 13 | 79.77% | 78.79% | 78.85% |
| 14 | 76.56% | 75.32% | 75.39% |
| 15 | 75.81% | 74.26% | 74.30% |
| 16 | 75.31% | 73.06% | 73.01% |
| 17 | 74.25% | 69.83% | 69.30% |
| 18 | 76.25% | 64.48% | 62.74% |
| 19 | 76.14% | 66.31% | 64.39% |

Table 3 below depicts an experimentally determined match length distribution. In Table 3, the Length column denotes the length of the matched strings in bytes. The Count column denotes the number of successful string matches of the given length. The Frequency column denotes the appearance rate of match of the given length as a ratio of total matches. The cumulative % column denotes the percent of all matches of the given length and below as a percentage of all matches. The Encoding column denotes the length in bits of the symbol used to indicate the string length in the compressed data in the preferred embodiment.

TABLE 3
Experimentally Obtained String Length Frequency Distribution

| Length | Count | Frequency | Cumulative % | Encoding |
|---|---|---|---|---|
| 3 | 74923 | 0.7836888 | 78.369 | 1 |
| 4 | 6167 | 0.0645063 | 84.820 | 3 |
| 5 | 3355 | 0.035093 | 88.329 | 3 |
| 6 | 1709 | 0.017876 | 90.116 | 3 |
| 7 | 1382 | 0.0144556 | 91.562 | 5 |
| 8 | 773 | 0.0080855 | 92.371 | 5 |
| 9 | 920 | 0.0096231 | 93.333 | 5 |
| 10 | 932 | 0.0097486 | 94.308 | 9 |
| 11 | 976 | 0.0102089 | 95.329 | 9 |
| 12 | 981 | 0.0102612 | 96.355 | 9 |
| 13 | 627 | 0.0065584 | 97.011 | 9 |
| 14 | 368 | 0.0038493 | 97.395 | 9 |
| 15 | 89 | 0.0009309 | 97.489 | 9 |
| 16 | 131 | 0.0013702 | 97.626 | 9 |
| 17 | 130 | 0.0013598 | 97.762 | 9 |
| 18 | 300 | 0.003138 | 98.075 | 9 |
| 19 | 50 | 0.000523 | 98.128 | 9 |
| 20 | 13 | 0.000136 | 98.141 | 9 |
| 21 | 218 | 0.0022803 | 98.369 | 9 |
| 22 | 62 | 0.0006485 | 98.434 | 9 |
| 23 | 108 | 0.0011297 | 98.547 | 9 |
| 24 | 39 | 0.0004079 | 98.588 | 9 |
| 25 | 48 | 0.0005021 | 98.638 | 13 |
| 26 | 6 | 6.28 E-05 | 98.644 | 13 |
| 27 | 2 | 2.09 E-05 | 98.646 | 13 |
| 28 | 99 | 0.0010355 | 98.750 | 13 |
| 29 | 11 | 0.0001151 | 98.762 | 13 |
| 30 | 1 | 1.05 E-05 | 98.763 | 13 |
| 31 | 36 | 0.0003766 | 98.800 | 13 |
| 32 | 274 | 0.002866 | 99.087 | 13 |
| 33 | 40 | 0.0004184 | 99.129 | 13 |
| 34 | 7 | 7.32 E-05 | 99.136 | 13 |
| 35 | 1 | 105 E-05 | 99.137 | 13 |
| 36 | 18 | 0.0001883 | 99.156 | 13 |
| 37 | 1 | 1.05 E-05 | 99.157 | 13 |
| 38 | 124 | 0.001297 | 99.287 | 13 |
| 39 | 105 | 0.0010983 | 99.396 | 13 |
| 40 | 1 | 1.05 E-05 | 99.398 | 13 |
| 41 | 153 | 0.0016004 | 99.558 | 17 |
| 42 | 45 | 0.0004707 | 99.605 | 17 |
| 43 | 104 | 0.0010878 | 99.713 | 17 |
| 44 | 9 | 9.41 E-05 | 99.723 | 17 |
| 45 | 35 | 0.0003661 | 99.759 | 17 |
| 46 | 1 | 1.05 E-05 | 99.760 | 17 |
| 47 | 48 | 0.0005021 | 99.811 | 17 |
| 48 | 98 | 0.0010251 | 99.913 | 17 |
| 49 | 14 | 0.0001464 | 99.928 | 17 |
| 50 | 4 | 4.18 E-05 | 99.932 | 17 |
| 52 | 1 | 1.05 E-05 | 99.933 | 17 |
| 57 | 6 | 6.28 E-05 | 99.939 | 17 |
| 58 | 17 | 0.0001778 | 99.957 | 17 |
| 59 | 41 | 0.0004289 | 100.000 | 17 |

Turning to the data decompression path 22 of FIG. 3, a compressed data packet is preferably received from the network and placed in an input buffer 40. The packet header is read by a header reader 42 to determine which if any of the static dictionaries have been used to compress the data to allow the corresponding static compression dictionary to be selected from the library 24 by a selector 44. A decompressor 46 then decompresses the data packet using the selected dictionary. Again, if the data packet was not compressed, then the decompressor 46 preferably carries out a null operation. The packet is then passed to an output buffer 48 for sending on along the network.

Considering the decompressor 46 in greater detail, it is responsible for decoding of compressed packets to restore the original data. Having selected the appropriate type specific dictionary from the library 24 the decompressor preferably carries out the algorithm given below in table 4, which is the complementary algorithm of FIG. 3. The input data is cycled through. If a “0” flag is encountered then the flag is removed and the following byte is retained as is. If a “1” is encountered then the flag is again removed and what follows is taken to be a dictionary reference. The reference is thus replaced with the string referred to in the dictionary, thereby to restore the data.

As the skilled person will be aware, implementation of the decompression algorithm of Table 4 may generally be expected to require less memory & CPU resources than the compressor 36, since data structures and algorithms required to find longest-match strings are not relevant in decompression. To obtain a dictionary string of a given position, a single memory access is required, and calculation is unnecessary. Thus, decompression is relatively fast compared to compression.

The skilled person will be aware that different compressor/decompressor pairs can use different sets of dictionaries, or different data types, for example when applying the present embodiment to different networks carrying statistically different data. However, as will be readily appreciated, a given data packet can be successfully decompressed only with the same dictionary used in its compression.

TABLE 4
Decompression Algorithm

Loop from beginning of data
Read current bit
If the bit's value is ‘0’:

Read 8 more bits and output them as a literal byte

(increment pointer by 8),

Otherwise:

Read the following bits as a table position (fixed size per

dictionary) and increment bit pointer by fixed size),

Read the bits following the table position as a length

(variable size, but uniquely defined) and increment the bit pointer by the
variable size,

Fetch the string of the given position & length from the

dictionary,

Copy the string to the output buffer,

increment the bit pointer,
Continue loop until end of packet.

In a modification of the decompressor 46, a feature is provided for determining that a packet, for which a decompression packet has been selected, has not in fact been compressed using the selected dictionary. Such a situation may arise for example from communication errors (e.g. channel noise) or from a 3^{rd} party's usage of a similar protocol. Such a feature preferably operates by recognizing out-of-range dictionary references. Once such a determination is made then the packet concerned is handled as a non-coded packet and output in its received form.

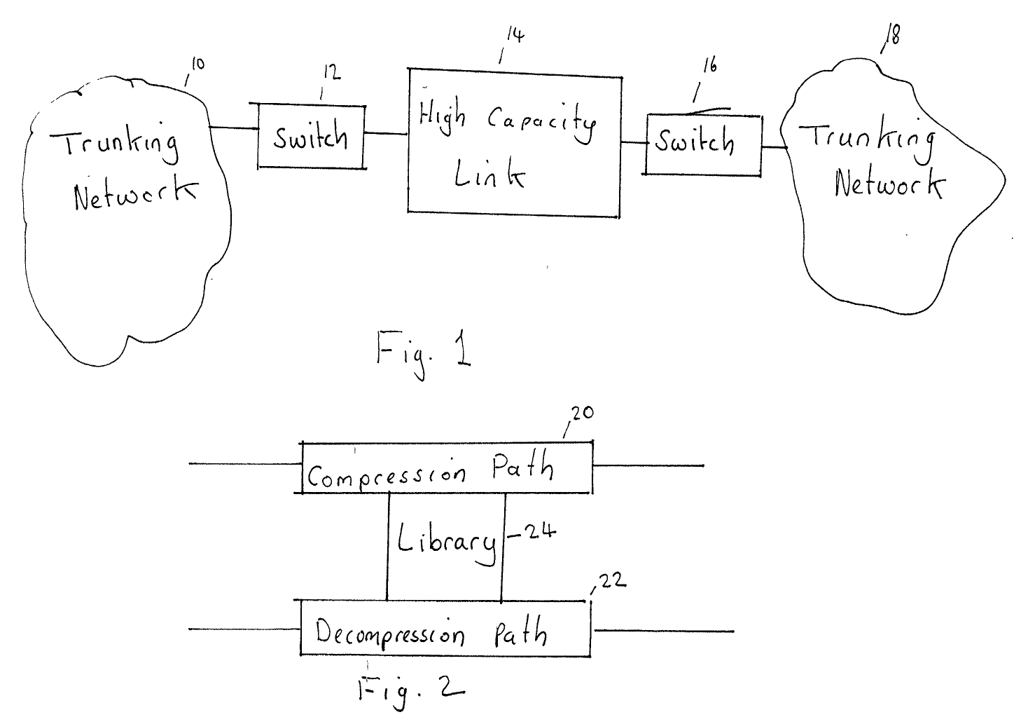

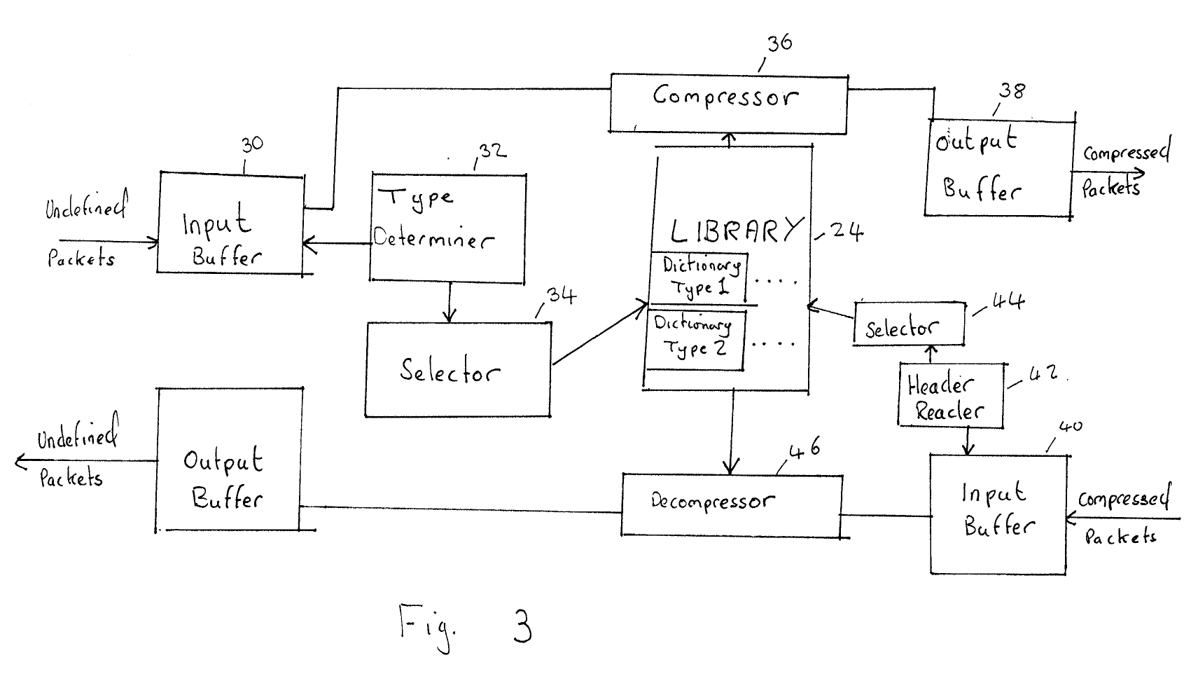

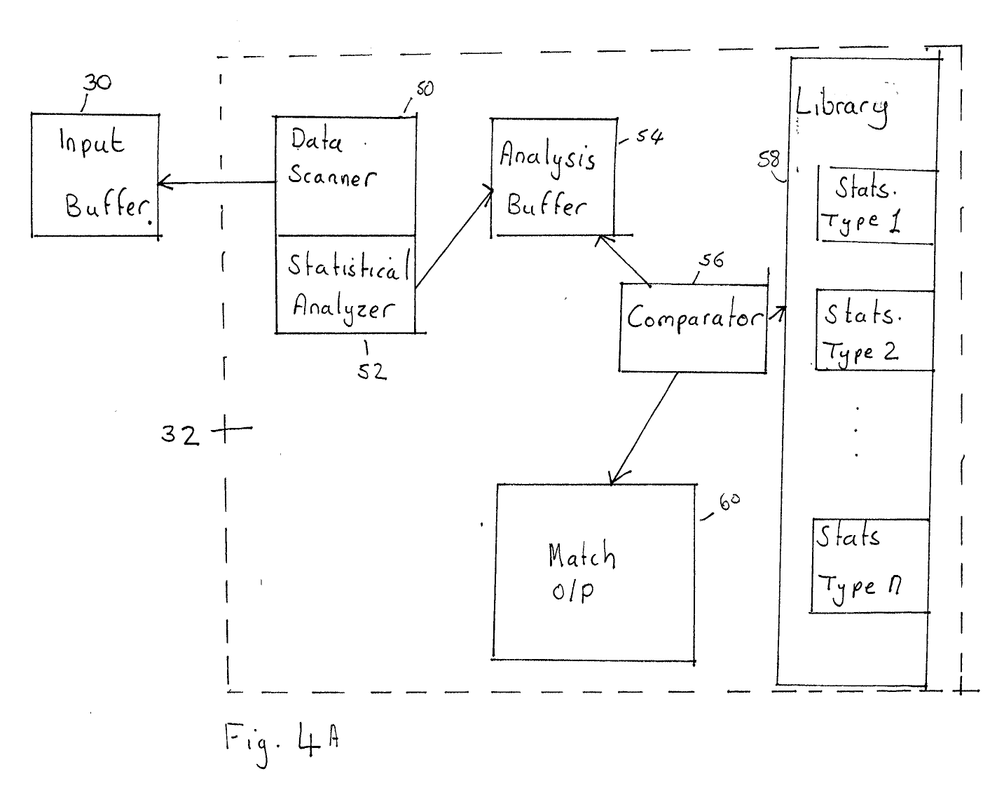

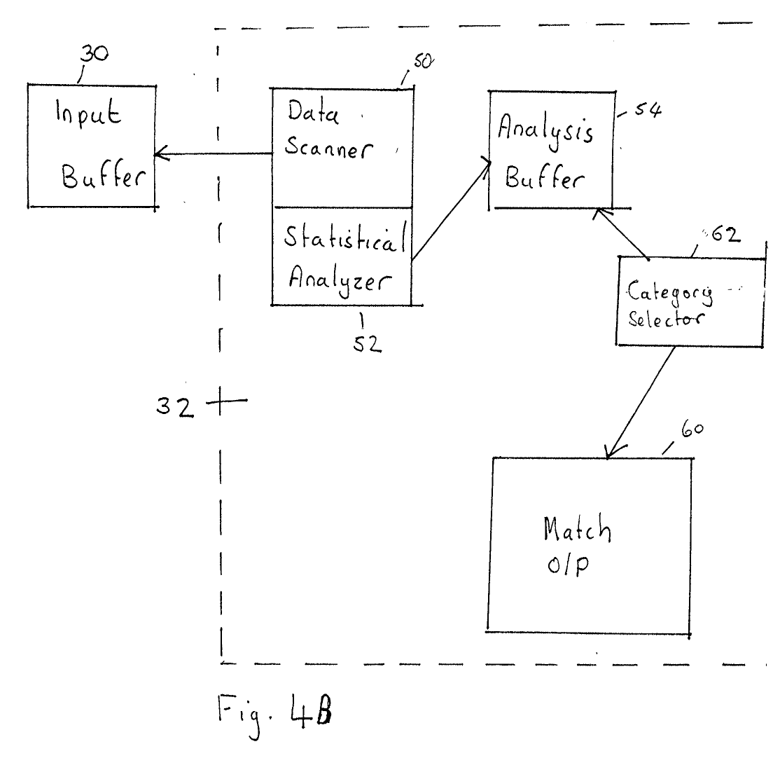

Reference is now made to FIG. 4A, which is a simplified block diagram showing in greater detail the operation of the type determiner 32. Parts that are identical to those shown above are given the same reference numerals and are not referred to again except as necessary for an understanding of the present embodiment. A data scanner 50 scans data from an incoming data packet to obtain information about the data content. The information about the data content is then passed to a statistical analyzer 52 which then operates on the data content to obtain a statistical analysis thereof to be placed in a buffer 54. The statistical analysis may typically comprise an analysis of the rate of occurrence of different characters.

The statistical analysis is then preferably used by comparator 56 to identify a closest match from a corresponding set of stored data type statistics from a library 58 of data type statistics. The comparator preferably uses approximate matching techniques to obtain a closest match from the sets in the library 58. A preferred method of approximate matching is to compute Hamming distances to each of the statistical sets in the library. Preferably a threshold is set so that if no computed Hamming distances are within the threshold then a failure to match is declared.

Reference is now made to FIG. 4B which is a simplified block diagram showing an alternative embodiment of the type determiner 32. In the alternative embodiment, the statistical analyzer 52 does not use a library of data sets but rather uses a simple algorithm, represented by category selector 62, to distinguish between three basic data types. The algorithm preferably provides a simple, fast method for categorizing incoming data packets into any one of three types or classes. The distinction is based on the statistical data preferably gathered in the form of character-appearance histograms for the various file types. The category selector 62 is able to recognize data types as follows:

1. Text: data, conventionally Ascii characters: including English text, most HTML data, etc.

2. Exec: Executable files.

3. Unknown: All other data types.

The analyzer 52 preferably uses a subset of the data in the incoming data packet to analyze, generally a fixed size string starting at a given offset within the data. An advantage of starting at a certain offset from the beginning rather than at the beginning itself is that generally the first few bytes of data within the packet are generally part of a packet header, thus confusing the classifier by not corresponding to the data type. Typically such data may consist of packet header information. It is therefore preferable to take characters from the middle of a packet, and not from the beginning. It is possible to vary the offset and/or select non-consecutive bytes of the data for analysis.

If a non-ASCII (or 8-bit) character is found within the selected string, then the packet is preferably marked as binary, i.e. it cannot belong to the class Text. A string that is binary may belong to either of the groups Exec or Unknown. A preferred method of identifying Exec data is to carry out a character count on the ‘0’ (zero) character. The method is based on the finding, from analysis of large numbers of PC executable files of various types and from different sources, that the character ‘0’ dominates the Exec file type, as illustrated below by Table 5, which shows experimental results of an analysis of the relative frequency of characters in executable files averaged over hundreds of PC executables of several types. Only characters with a frequency of more than 1% are shown. The abundance of the ‘0’ character, that makes the Exec type of file easily recognizable (and compressible) is clearly evident.

Using only three data types, a statistical analyzer according to the present embodiment is able to provide a significant overall increase in compression, is simple to implement and is able to operate very rapidly.

The above-described method leaves large numbers of packets classified as unknown, namely any binary packet that does not have a preponderance of the character “0”. It is generally true of network packets that packets of type Unknown have little redundancy, typically because they have already been

TABLE 5
Frequency of 8 - bit characters in EXEC files

| ASCII | Appearance |
|---|---|
| character | frequency |
| 0 | 0.235939 |
| 1 | 0.013522 |
| 4 | 0.015911 |
| 8 | 0.024706 |
| 32 | 0.015364 |
| 36 | 0.014506 |
| 116 | 0.015649 |
| 131 | 0.014158 |
| 137 | 0.011726 |
| 139 | 0.02308 |
| 232 | 0.011634 |
| 255 | 0.040135 |

compressed or encrypted by the sending application. Such packets are thus preferably not compressed by the present embodiments, thereby reducing the strain on the CPU, but rather are ignored.

Character frequency analysis using a comparison of character counts with prestored frequency tables may be used to distinguish different kinds of text (HTML, JavaScript, text & classes of text, etc), text in other languages that use 8- or 16-bit characters (Hebrew, Kanji, and so forth), and can permit further analysis of the Unknown class as defined above. It is pointed out that, the more sophisticated the analysis, the greater is the quantity of data from the packet that needs to be sampled to provide a reliable categorization.

A further preferred embodiment of the analyzer 32 uses any one of a range of classification algorithms from information theory, including Bayesian Classifiers.

The output of the comparator 56 or selector 62, indicating a matched statistical set or a match failure, is preferably passed to a match output unit 60 for use in selecting the dictionary to be used by the compressor as discussed above.

As has been explained above, the compressing process itself simply refers to an individual dictionary in the library and does not update or build while compressing. Appropriate selection of the best dictionary requires some knowledge of the data to be compressed for the dictionaries to be effective and this is preferably obtained by the statistical analysis outlined above. On the other hand, the compressor process does not need to spend computer resources on dictionary building & maintenance, and needs to store no dictionary building information in the compressed output. This, combined with a well-suited pre-built dictionary can yield a better and more rapid compression than conventional compression methods. There follows a preferred method and apparatus for building a library of well-suited dictionaries. It is of course to be appreciated, as has been mentioned hereinbefore, that the embodiments are not limited to the use of static dictionaries. Rather the embodiments may use packet type detection to associate any data packet with any specific compression type in order to carry out compression more efficiently.

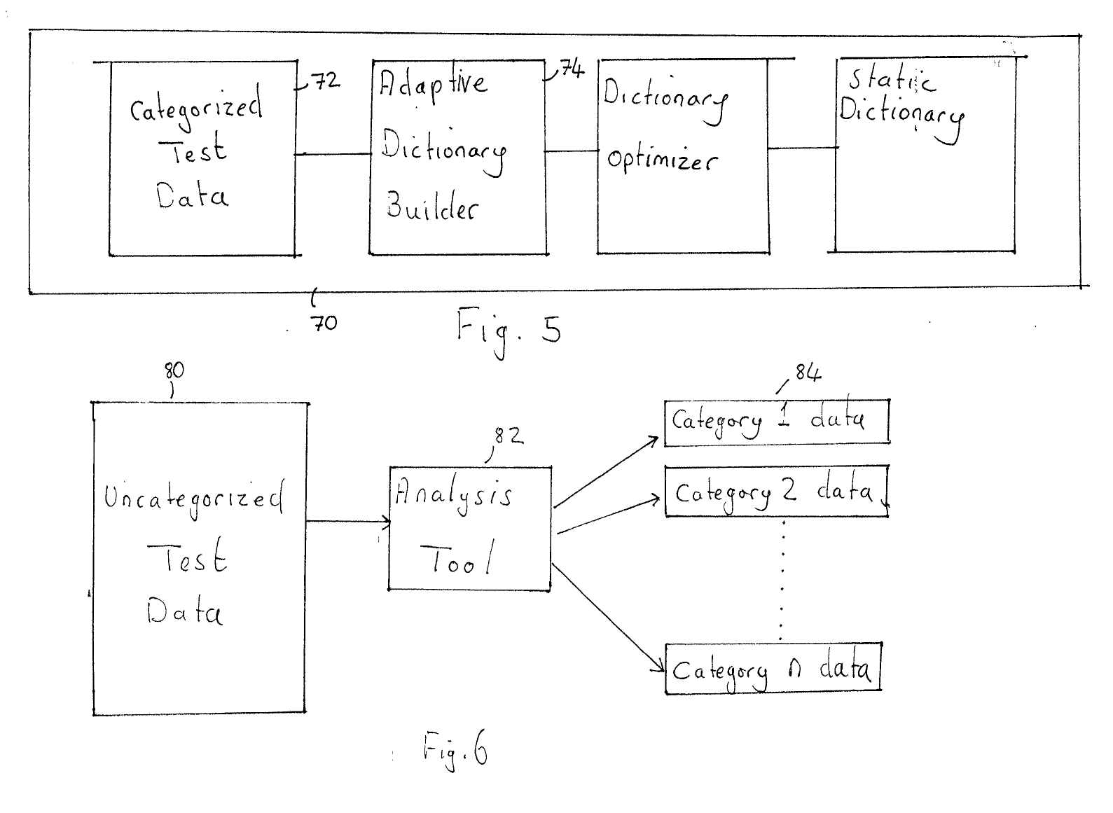

Reference is now made to FIG. 5, which is a simplified block diagram of a static dictionary creator in accordance with a preferred embodiment of the present invention. A static dictionary creator 70 comprises a first memory device 72 storing a statistically significant and representative sample of data according to a given data type. In this embodiment it is assumed that the data types are predefined and that data of each of the predefined types is readily available. For example the data type may be English text in which case the sample is preferably a large quantity of text in English. The sample may either be randomly chosen or deliberately selected to cover a wide range of subjects and styles.

In more detail, a statistically representative set of data units is gathered to provide sample data for the given data type. Since the exact data to be compressed is not known at the dictionary building stage, a statistically large and representative data set is preferably obtained. The obtaining of such a representative data set may possibly involve statistical analysis of real data to form the set.

The data sample is then used by an adaptive dictionary builder 74 to build a dictionary optimized to the data sample. Any known adaptive dictionary building technique may be used and, provided the data sample is sufficiently representative, the dictionary that is produced is effective for most samples of English text likely to be encountered.

In an embodiment, the size of the dictionary is not predefined or prelimited as such, although it is dependent on the compression method chosen, resulting compression performance and available resources. In the embodiment, the adaptive dictionary builder 74 scans the entirety of the categorized test data 72 and finds all occurrence of substrings in a given length range whose frequency count in the test data 74 exceed a predetermined threshold. The collection of these strings provides a basic but usable dictionary.

A further preferred embodiment scans all the strings in the test data 74 and uses an evaluation function to determine the merit of each string as a dictionary string, subsequently selecting the strings having the highest evaluated merits (upto a given limit) for the dictionary. A preferred evaluation function weighs both the length and the frequency of the string in a formula that predicts how many bits may be reduced from the data subset if it were to be compressed with a dictionary containing this string. For example, if a certain string has 16 bits and, due to its frequency it can be ranked at such a position that it can be referred to using a reference having 8 bits, then the predicted reduction would be 16−8=8 bits per occurance. Separate consideration has also to applied to the frequency of occurance of the string to obtain an overall benefit. A long string appearing a small number of times could could result in better or worse overall compression than a short string appearing relatively frequently.

Preferably, the dictionary built by the adaptive dictionary builder 74 is passed to the dictionary optimizer 76. The dictionary optimizer 76 preferably refines the resulting string list by merging strings or substrings having common prefixes and suffixes, thereby to save space (and thus the length of the referring strings) in the resulting dictionary. For example, given strings “abcdef” and “cde”, it is sufficient to keep the former and remove the latter since a pointer to the “c” in the former with a length of 3 renders the latter redundant. Such optimization in turn improves compression performance and may permit more strings to be inserted into the dictionary.

As will be appreciated from the above, the static dictionary library is built before the compression process is carried out and thus it is possible to build the library using much larger and more powerful computing resources than would typically be available to the individual user.

Reference is now made to FIG. 6, which is a simplified diagram showing an apparatus for automatic categorizing of sample data into data types for use in the dictionary creator. In FIG. 6, uncategorized test data 80 is obtained directly from a data source. Preferably the uncategorized test data comprises a statistically very large sample, sufficiently large that when the data is divided into types or categories, there will be sufficient data in each category also to constitute a statistically large sample. An analysis tool 82 analyses the uncategorized test data 80 to find patterns that repeat themselves across parts of the data and which patterns can be used to define data types.

The analysis tool 82 preferably comprises statistical and information-theoretic analysis tools to find information classes within the data, meaning parts of the data that are statistically different in terms of character distribution. One preferred embodiment actually uses various compression schemes or dictionaries to find similarities between data units and thereby to categorize such data units as belonging to a given class. In one such embodiment the data items are compressed using a dictionary set up for a particular character distribution. All data items that are found to have been compressed efficiently by the same data type specific dictionary are categorized in a given data type.

Another preferred embodiment of an analysis tool counts the frequencies of special characters, or the abundance of special keywords. Thus a certain frequency order of characters indicates the presence of English text. A similar but different order of characters indicates German text. A completely different distribution of characters with a large proportion of zeroes may be characteristic of executable code and so on.

The analysis tool provides information regarding patterns found in the data enabling a choice to be made about data types for inclusion in the library. The choice to be made depends, however, not only on whether distinctions can be made between the data types in the analysis tool 82 but also whether it is feasable to distinguish between the data types as they may appear in short length packets in use. In other words not only is it necessary to find statistically distinct data groups, it is also important to take into account the distance between the groups. Thus for example it may be possible for the analysis tool to distinguish on the basis of character frequency between British English and American English on the basis of the letter “Z” being relatively much more common in American English. However such a difference is unlikely to show up in an analysis of a short data packet and thus it would not be optimal in most cases to supply separate dictionaries for British and American English. The selection of data classes may be performed either manually or automatically.

On the above basis, the data is broken down into categories 84 for use by the dictionary creator 70.

Considering the process of creating a dictionary in greater detail, the static dictionaries are preferably created by the dictionary creator 70 as described above using the analysis tool of FIG. 6 to analyze data files into data types or categories for which representative dictionaries can be made. The process of dictionary creation may require considerable CPU & memory resources if the test data is large, as it preferably is. However, implementation is relatively simple using the so-called Dictmake algorithm given below in Table 6 which finds repeated strings in the data, uses an evaluation function to grade the repeated strings in terms of frequency and other parameters and then places the strings in the dictionary in order of the grading until the dictionary is full.

The success of the algorithm of table 6 is dependent on the evaluation grade given to the individual strings. A good evaluation function preferentially selects strings that represent good choices for a compression dictionary. The evaluation function is based on the following principles:

Replacement of a string by a dictionary reference leads to compression if the string being replaced is frequent enough and/or is long enough.

On the other hand, a string that is replaced by a dictionary reference has a cost: the length of the dictionary reference that replaces it.

A preferred evaluation function is described thus:

g(s)=count(s)×(8·|s|−refsize)

TABLE 6
Dictmake Algorithm

Count appearances of all data strings of a given length range (e.g. 3

to 64 characters)

Give an evaluation grade to each string above a threshold

appearance frequency

Sort evaluated strings in descending grade order
Starting with an empty dictionary string, begin loop:
Get next string according to sort order
If the next string isn't already contained in the dictionary as a

substring, insert it into the dictionary

Continue loop till the desired dictionary maximum size is reached,

or the strings are exhausted

Where s is a string, count(s) represents its frequency count, |s| represents its length in bytes and refsize is the length in bits of a dictionary reference. The function g(s) gives a measure of the number of bits that are gained by replacing s with its dictionary reference in the data to be compressed.

The following functions are also feasible for use in evaluation:

g(s)=count(s)×(8·|s|)

g(s)=(count(s)−1)×(8·|s|−refsize)

The first of the functions ignores the effect of the dictionary reference size and the other considers the space the string may occupy in the dictionary.

Considering the structure of the dictionary in further detail, the static dictionary is an important factor in compression and decompression performance The static dictionary of a preferred embodiment is simply one long string or buffer, with a set of operators to retrieve substrings therefrom Its size is generally 2^{P} bytes where P is called the pointer size. P ranges in the art between values of 7 and 32, but is preferably chosen from a much smaller domain, about 15-20 bits: 7-bit dictionaries (128 Bytes) are generally found to be too small to contain useful strings for compression. Beyond about 20, the dictionaries consume large amounts of memory and take a lot of CPU time to handle without providing commensurate benefits in terms of improved compression performance.

A static dictionary, may be provided as part of a self-contained module comprising the dictionary itself together with functionality components as necessary, typically construction, destruction, match searching and string fetching. The construction functionality component for example may correspond to the dictionary creator 70. The match searching functionality component is preferably used as part of on-line compression and is thus the most critical of the run time components in the module. Construction & destruction are performed on setup only, and string fetching for a given reference is a relatively trivial operation. To achieve fast match searching, in one preferred embodiment, a technique known as chained hashing is used. Chained hashing involves an open hash table with what are known as chained buckets. In more detail a hash table is a data structure that allows storage and retrieval of data items in relatively short, almost constant time. Access to data in the hash table is achieved by means of a function (hash function) that computes a table entry number from a given data item. A perfect hash function would be expected to produce different hash values (table entries) for different data items. Many hash functions are not perfect and could for example produce the same hash value for different data items, resulting in what are known as hash table conflicts.

There are several techniques to override the problems that arise from hash table conflicts. One such technique is called chaining: If one inserts or retrieves data items from a table entry to which another data item is also inserted (that is since both compute the same hash value), one creates a linked list (chain) of data items. The first data item is stored in the hash table entry, and contains a pointer to the next data item, typically allocated at a space outside the hash table. The next data item in turn includes a pointer to a further succeeding item and so forth, until all the data items are enumerated. A good hash function with a large enough table would produce an average list length that is short enough to enable quick searches into the table. Data objects are usually of constant size, and that is also the case with the hash table used in the present embodiments. The (constant) space reserved for a data item is referred to herein as a bucket. Thus, reference herein to a hash table with chained buckets means a hash table that resolves hash conflicts by chaining an additional bucket for each newly inserted data item to a table entry that is used by another data item.

In the hash table embodiment using chained buckets as described above, an implementation of the dictionary optimizer 76 comprises adding functionality to the dictmake algorithm of table 6 to enable it to fine-tune a hash function to enable more efficient referencing of the strings in the dictionary. Optimally, if a minimal hash function is found, the compressor's performance can be boosted since all hash hits and misses, that is to say each query, can be determined in a single hash table access. When bearing in mind that most of the compressor's time is spent on hash table/dictionary misses, that is to say every tested string, even those that eventually encompass a successful replacement with a dictionary reference (and most are not) must by definition incur one dictionary miss, it will be appreciated that the use of a hash table can provide a considerable saving in resources provided that the hash table is well constructed.

During the dictionary construction process an initialization procedure takes place, typically comprising memory allocation, variable setting and calculation of a required pointer size. Then the dictionary module receives a series of strings to be incorporated into the dictionary, for example using the dictmake algorithm above. A hash-table data structure is then filled in using the algorithm of Table 7 below:

TABLE 7
Building a hash table during dictionary creation

Loop over all dictionary-string's positions pos:
1 set len <- MIN_STRING_LENGTH (3)
2 find hash value h for string of length len starting at pos
3 If hash table at entry h is empty, put pos at entry h
4 Otherwise if table entry h or any of its buckets does not contain pos (a
collision), add a bucket to h and put pos in bucket.
5 If pos was found in h or its buckets, increment len and continue with
step 2

Referring to table 7, the hash table initially attempts to store references to all 3-character length sub-strings that appear in a dictionary buffer of strings that are being sent to be incorporated in the dictionary. In the event of an attempt to give two different strings an identical hash value, a situation known as a normal collision situation, the collision situation is resolved by linked-list chaining. However, when a string to be inserted already exists in the hash table, the string is enlarged by one character, namely the next character to appear in the input buffer, and a further attempt is made to insert it into the hash table.

Match searching in the compressor 36 generally consists of finding the longest string in the dictionary that matches a given input string. A return value is obtained which comprises a position in the dictionary string, and the length of the match. Alternatively, the return value may simply comprise an indication that no such match of minimal length was found. A preferred matching algorithm for a given input string s using the hash table embodiment is given in table 8 below. The algorithm of table 8 moves character-wise through the input buffer until it has a minimal number of characters, in this case 3. The three characters are looked up in the hash table. If they are found then the reference thereto in the dictionary is retained and a fourth character is added from the input buffer and that too is searched for. Characters are continually added until a search fails to find the current set of characters. Upon failure, the previous result, that is the reference to the place in the dictionary storing the last set of characters, is used to form the compressed data.

Returning to the subject of dictionary building, and another preferred embodiment further optimizes the dictionary using a string merging heuristic that eliminates duplicate sub-strings from the dictionary, and “grows” better strings from string fragments. Two such string merging heuristics are described as follows:

TABLE 8
String Matching using a hash table

1 len <- MIN_STRING_LEN (initailised with value of 3)
2 find location in hash table of the string consisting of the first len
characters of s, using hash function and buckets.
3 if no such location is found, indicate failure & return
4 if found, increment len and retry till failure
5 return the last location and len before failure

The first algorithm for a string merging heuristic is of a kind referred to in the art as a greedy algorithm. It attempts to merge every dictionary-inserted string with every other string that has not yet been inserted. It selects the best, i.e. most useful merged strings, preferably selected using an efficiency measuring algorithm of the kind referred to above.

A second, more complex, algorithm for a string merging heuristic represents all candidate strings as vertices in a graph. Edges are then constructed to link each combination of vertices such that the edges symbolically represent the merger of the strings in the combination, and the edges are assigned a weight representing similarity between the strings. The algorithm preferably proceeds to merge strings (vertices) according to the weights assigned to the respective edges in an iteration that ends when no more mergers are possible.

String merging is not restricted to the two algorithms described above but the skilled person will be aware of the possibility of using a wide range of methods of string merging in an iterative process of dictionary improvement.

In experimental testing, a utility for compressing packets was written and used. Two data sets were used for the measurements, the first being a set of 143 5000-packet samples, totaling 385,489,253 bytes of sample payload. The entire data set was compressed using a prototype of the present embodiments The data set exhibited high variability and the dictionaries used in the test were all 18-bit (256 Kb) dictionaries.

Two sets of performance measurements were taken. The first test tried to compress all three of the data types Text, Exec and Unknown, while the second ignored class Unknown packets. Both achieved a similar compression ratio: 89.18% and 89.86% respectively (i.e. obtaining an approximate 10% increase in network bandwidth). The data processing rate however exhibited a significant gap. While the first test averaged a 12.27 Mbit/sec data rate, the second test that ignored type Unknown packets averaged 54.01 Mbit/sec (A 4.4 fold improvement). The results suggest therefore that compression of type Unknown packets adds considerably to the time and effort with very little commensurate advantage in increased compression.

Compression ratios obtained for packets of each type within the experiment is as follows: Type Text predictably obtained the best average ratio viz 69.01%. Next came class Exec with 80.54% and class Unknown obtained the modest ratio of 98.9%.

The second data set was a dump-file of 1000 IP packets (approx 440 KB) collected, not at random, but from a single user browsing the Internet. The idea of the experiment was to determine how effective the prototype would be in the face of a statistical skew of data packets. The sample was determined to be sufficiently unrepresentative to represent a real world statistical skew. The compression ratios and compression speed (in Mbit per second) are presented against dictionary size in table 9 below. They should not be taken as representative due to the small size of the data set, but rather as a demonstration of abilities in more specific data sets.

TABLE 9
Compression Ratios for Uncorrelated Data packets

| Bits | Speed | Ratio |
|---|---|---|
| 10 | 18.414 | 76.61% |
| 11 | 18.547 | 74.13% |
| 12 | 18.026 | 71.69% |
| 13 | 17.95 | 67.97% |
| 14 | 17.561 | 65.98% |
| 15 | 17.292 | 65.15% |
| 16 | 18.277 | 62.85% |
| 17 | 21.617 | 58.89% |
| 18 | 24.557 | 58.48% |
| 19 | 24.645 | 61.00% |
| 20 | 24.535 | 63.63% |

There is thus provided a system for categorizing small data units and compressing them using an appropriate static dictionary, which system is particularly but not exclusively applicable to switches located in data networks.

It is appreciated that certain features of the invention, which are, for clarity, described in the context of separate embodiments, may also be provided in combination in a single embodiment. Conversely, various features of the invention which are, for brevity, described in the context of a single embodiment, may also be provided separately or in any suitable subcombination.

It will be appreciated by persons skilled in the art that the present invention is not limited to what has been particularly shown and described hereinabove. Rather the scope of the present invention is defined by the appended claims and includes both combinations and subcombinations of the various features described hereinabove as well as variations and modifications thereof which would occur to persons skilled in the art upon reading the foregoing description.

1. Dictionary based data compression apparatus comprising
a library of static dictionaries, comprising at least two static dictionaries each optimized for a different data type,
a data type determiner operable to scan incoming data and determine a data type thereof,
a selector for selecting a static dictionary corresponding to said determined data type and
a compressor for compressing said incoming data using said selected dictionary.

2. Dictionary based data compression apparatus according to claim 1 wherein said incoming data comprises unrelated data packets, each data packet being of insufficient length to permit efficient adaptive compression.

3. Dictionary based data compression apparatus according to claim 2, wherein said data type determiner is operable to assign a data type to individual packets.

4. Dictionary based data compression apparatus according to claim 2 wherein said data types include an unknown type and wherein said compressor is operable not to compress a packet classified as unknown.

5. Dictionary based data compression apparatus according to claim 1, wherein said data types include at least one text type.

6. Dictionary based data compression apparatus according to claim 5, wherein said text type comprises statistically spaced text sub-types.

7. Dictionary based data compression apparatus according to claim 1, wherein each dictionary comprises a hash table to optimize searching of said dictionary.

8. Dictionary based data compression apparatus according to claim 1, incorporated within an interface to a high capacity data link.

9. Dictionary based data compression apparatus according to claim 1, wherein said data type determiner is operable to obtain a statistical analysis of relative character frequency from said data, thereby to determine said data type.

10. Dictionary based compression apparatus according to claim 1, wherein said compressor is further operable to tag compressed packets to indicate said selected dictionary.

11. Dictionary based compression apparatus according to claim 2, wherein said data type determiner is operable to obtain a sample of the data within the packet for scanning and wherein the sample is taken from a position offset from a start of the packet by a predetermined offset, thereby to avoid selecting a sample from a packet header.

12. A method of compressing data comprising:
scanning incoming data to determine a data type,
selecting, from a library of static dictionaries, a static dictionary optimized for said determined data type,
and compressing said incoming data using said selected dictionary.

13. A method of compressing data according to claim 12, wherein said incoming data comprises data characters, the method comprising determining a data type by analyzing relative character content of said data and comparing said relative character content with characteristics of each data type thereby to determine a closest matching data type.

14. A method of compressing data according to claim 13, wherein said data types comprise a data type for machine executable data which type is identified by a preponderance of the zero character.

15. A method of compressing data according to claim 14, wherein said data type for machine executable data is further classified into data subtypes for machine architecture.

16. A method of compressing data according to claim 12, wherein said data is arranged in data packets and wherein scanning of data is carried out on a sample taken from a position offset from a packet start by an offset sufficiently large to avoid packet header data.

17. A method of compressing data according to claim 12, further comprising tagging the data to indicate said static dictionary selection.

18. A method of compressing data according to claim 12, wherein said data types include an “unknown” data type and which method is operable to perform a null compression on data classified as type “unknown”.

19. A method of compressing data according to claim 12, wherein said dictionaries in said library comprise hashing tables to enable easy searching.

20. A method of compressing data according to claim 12 wherein said data types comprise at least one text data type.

21. Dictionary based decompression apparatus comprising a library of static dictionaries each optimized for a different data type,
a dictionary determiner operable to scan incoming data and determine a data type of a dictionary used to compress said data,
a selector for selecting a static dictionary corresponding to said determined data type and
a decompressor for decompressing said incoming data using said selected dictionary.

22. Dictionary based decompression apparatus wherein said data is arranged in packets having packet headers and said dictionary determiner is operable to search a packet header of an incoming packet to find a tag inserted by a corresponding compression apparatus to indicate said data type.

23. Dictionary based decompression apparatus according to claim 22, wherein said decompressor is operable to carry out a null compression operation on any packet identified by said tag as not having a selected data type.

24. Dictionary based decompression apparatus according to claim 23, wherein a compression performance threshold is set, and said compressor is operable to reidentify any data type whose compression does not reach said performance threshold as being of unknown type.

25. Dictionary based decompression apparatus according to claim 21, wherein said decompressor comprises an LV type decompression procedure.

26. Dictionary based decompression apparatus according to claim 21 wherein said data types include at least one text data type.

27. Dictionary based decompression apparatus according to claim 21, wherein said data types include at least one executable data type.

28. Dictionary based decompression apparatus according to claim 21 further comprising a bogus data identifier operable to stop a current decompression operation if a current data packet associated with a given dictionary appears to contain data out of a range of said dictionary.

29. A method of decompressing data comprising,
receiving data that has been compressed using one of a plurality of static dictionaries from a static dictionary library,
determining from said received data which one of said plurality of dictionaries has been used to compress said data, and
decompressing said data using said determined dictionary.

30. A method according to claim 29, wherein said data is in the form of data packets having headers and wherein said determining is carried out by identifying an indication tag within said packet header.

31. A method of compressing data according to claim 29, wherein said dictionaries include a dictionary for machine executable data.

32. A method of compressing data according to claim 30, wherein said packets further include an “unknown” packet type and which method is operable to perform a null decompression operation on packets identified as type “unknown”.

33. A method of compressing data according to claim 29 wherein said data types comprise at least one text data type.

34. A method according to claim 29, wherein said decompression includes checking said data to ensure that it is within a range of said selected dictionary and aborting said decompression if it is outside a range of said dictionary.

35. Apparatus for building a library of static compression dictionaries, said apparatus comprising
test data categorized into a plurality of data types,
an adaptive dictionary builder for building dictionaries optimized for an input data set,
an input unit for inputting, to said adaptive dictionary builder, test data of a single data type for each one of a plurality of dictionaries to be built,
and a memory for storing a plurality of dictionaries, each built using a different test data type, thereby to form a library of static compression dictionaries.

36. Apparatus according to claim 34, said adaptive dictionary builder comprising LZ type dictionary building functionality.

37. Apparatus according to claim 36, said adaptive dictionary builder further comprising a hash table constructer for constructing a hash table for rapid searching of said dictionary.

38. Apparatus according to claim 35, wherein said adaptive dictionary builder comprises a string evaluation unit for assigning compression utility values to repeated strings identified within said data, thereby to provide a relative prioritization for incorporation of said data strings into said respective dictionary.

39. Apparatus according to claim 38, wherein said string evaluation unit is operable to generate a string utility value by computing a difference between a length of a given string and a length of a reference of a position thereof in a dictionary.

40. Apparatus according to claim 39, wherein said string evaluation unit is operable to order evaluated strings in an order of respective string utility values.

41. Apparatus according to claim 35, comprising a dictionary optimizer for optimizing each respective dictionary by merging similar strings incorporated within said dictionary.

42. Apparatus according to claim 35, comprising a dictionary optimizer for optimizing each respective dictionary by merging strings entered into said dictionary using a string merging heuristic.

43. A method of building a static dictionary library, the method comprising:
inputting test data,
categorizing said test data into a plurality of data types,
building an adaptively optimized dictionary for each one of said data types, and
storing each adaptively optimized dictionary together to form said library.

44. A method according to claim 43, wherein said building of said dictionary comprises using an LZ type dictionary building process.

45. A method according to claim 44, further comprising constructing a hash table for rapid searching of said dictionary.

46. A method according to claim 45, comprising assigning compression utility values to repeated strings identified within said data, thereby to provide a relative prioritization for incorporation of said data strings into said respective dictionary.

47. A method according to claim 46, comprising generating a string utility value by computing a difference between a length of a given string and a length of a reference of a position thereof in a dictionary.

48. A method according to claim 47, further comprising ordering evaluated strings in an order of respective string utility values.

49. A method according to claim 47, further comprising ordering evaluated strings according to frequency.

50. A method according to claim 42, comprising optimizing each respective dictionary by merging similar strings incorporated within said dictionary.

51. A method according to claim 42, comprising optimizing each respective dictionary by merging strings entered into said dictionary using a string merging heuristic.

52. A method according to claim 42 wherein categorizing said data comprises making character frequency analyses of said data and associating together data having a similar character frequency characteristic.

53. A method of building a static dictionary library, the method comprising:
inputting test data categorized into a plurality of data types,
building an adaptively optimized dictionary for each one of said data types, and
storing each adaptively optimized dictionary together to form said library.

54. A method according to claim 53, wherein said building of said dictionary comprises using an LZ type dictionary building process.

55. A method according to claim 53, further comprising constructing a hash table for rapid searching of said dictionary.

56. A method according to claim 53, comprising assigning compression utility values to repeated strings identified within said data, thereby to provide a relative prioritization for incorporation of said data strings into said respective dictionary.

57. A method according to claim 56, comprising generating a string utility value by computing a difference between a length of a given string and a length of a reference of a position thereof in a dictionary.

58. A method according to claim 57, further comprising ordering evaluated strings in an order of respective string utility values.

59. A method according to claim 53, comprising optimizing each respective dictionary by merging similar strings incorporated within said dictionary.

60. A method according to claim 53, comprising optimizing each respective dictionary by merging strings entered into said dictionary using a string merging heuristic.

61. A method according to claim 53, wherein said adaptively organized dictionaries are each of different size.

62. A method according to claim 54, wherein said adaptively organized dictionaries are each usable in incompatible compression procedures.

63. Apparatus for classifying incoming data, comprising:
a data scanner for scanning incoming data to provide a statistical analysis thereof, and
a type associator for using data of said statistical analysis to step through characteristics of predetermined data types, thereby to associate said data with one of said data types.

64. Apparatus for classifying incoming data, comprising:
a library comprising statistical data sets for each one of a plurality of data types,
a data scanner for scanning incoming data to provide a statistical analysis thereof,
a type matcher for finding a closest matched between said analyzed data and said statistical data sets, thereby to determine a most probable data type of said incoming data.

65. A method of classifying incoming data in accordance with a library of data types, comprising:
scanning incoming data to obtain a statistical analysis thereof,
using said statistical analysis to step through a series of data type characteristic selection rules,
determining a closest match between said incoming data and said respective data types from said selection rules,
thereby to obtain a most probable data type of said incoming data.

66. A method of classifying incoming data in accordance with a library of data types, comprising:
scanning incoming data to obtain a statistical analysis thereof,
comparing said analysis with each one of a plurality of sets of statistics each corresponding to a respective data type in said data type library, and
determining a closest match between said incoming data and said respective data types,
thereby obtaining a most probable data type of said incoming data.

67. A selective packet compression device comprising:
a packet classifier for classifying incoming data packets into precompressed packets and non-compressed packets and
a compressor connected to said packet classifier to be switchable by said packet classifier to compress packets classified as non-compressed packets and not to compress packets classified as precompressed packets.

68. A selective packet compression device according to claim 67 wherein said incoming data comprises unrelated data packets, each data packet being of insufficient length to permit efficient adaptive compression.

69. A selective packet compression device according to claim 68, wherein said data type determiner is operable to assign a data type to individual packets.

70. A selective packet compression device according to claim 68 wherein said data types include an unknown type and wherein said compressor is operable not to compress a packet classified as unknown.

71. A selective packet compression device according to claim 67, wherein said data types include at least one text type.

72. A selective packet compression device according to claim 71, wherein said text type comprises statistically spaced text sub-types.

73. A selective packet compression device according to claim 67, wherein each dictionary comprises a hash table to optimize searching.

74. A selective packet compression device according to claim 67, incorporated within an interface to a high capacity data link.

75. A selective packet compression device according to claim 67, wherein said data type determiner is operable to obtain a statistical analysis of relative character frequency from said data, thereby to determine said data type.

76. A selective packet compression device according to claim 67, wherein said compressor is further operable to tag compressed packets to indicate said selected dictionary.

77. A selective packet compression device according to claim 68, wherein said data type determiner is operable to obtain a sample of the data within the packet for scanning and wherein the sample is taken from a position offset from a start of the packet by a predetermined offset, thereby to avoid selecting a sample from a packet header.

78. A selective packet compression method comprising:
classifying incoming data packets as compressed packets and non-compressed packets,
compressing those incoming data packets classified as non-compressed packets, and
not compressing those incoming data packets classified as compressed packets.

79. A static compression dictionary library comprising:
a plurality of individually selectable static compression dictionaries, each dictionary being optimized for compression of data of a predetermined data type.

80. A method of classifying a data packet into one of a plurality of data types based on character content of the data of the packet, the method comprising:
obtaining a first data string beginning at a predetermined offset from the beginning of the packet,
analyzing the data string for character distribution, and
classifying the packet based on the character distribution.

81. A method according to claim 80, comprising obtaining a second string at a predetermined offset from said first string and analyzing said second string for character distribution.

82. A compressor for compressing data by replacing data with a corresponding start position and a length of a location of said data in a data dictionary, said replacements giving a statistical correlation between length and frequency such as to provide a progression between more frequent lengths and less frequent lengths, the compressor comprising an encoder operable to encode said lengths such that said statistically more frequent lengths are encoded using shorter codes than said statistically less frequent lengths, a statistically most frequent length being encoded with a shortest code.

83. A method of building a hash table for a string-based compression dictionary, said string-based compression dictionary comprising a string of concatenated repeating data portions of target compressible data, parts of the string being referable by a start position and a length, the method comprising:
passing through all positions on said string, and
for each position on said string repeating for all string lengths between a minimum string length and a maximum string length:
computing a hash value for the string part at the current position and having the current string length,
entering the current position in the hash table at a position of the computed hash value if said position of the computed hash value is empty, and
entering the current position at a subsidiary position of said computed hash value if said position of said computed hash value is already occupied.

84. A method of finding a location of a longest string part within a string based compression dictionary referenced via a hash table with table entries and associated sub-entries, and an associated hash function, the method comprising:
applying successively incrementally increasing lengths of said string part to said hash function to obtain a hash result,
applying said hash result to said hash table to obtain a location in said dictionary,
and when a location is not retrieved from said hash table then providing a last previous obtained location as an output if a preceding incrementally increasing length of said string yielded a location, and otherwise indicating a retrieval failure.
